(19) United States
(12) Patent Application Publication
(10) Pub. No.: US 2024/0295368 A1
(43) Pub. Date: Sep. 5, 2024

(54) WATER-COOLING STRUCTURE

(71) Applicant: PEGATRON CORPORATION, TAIPEI CITY (TW)

(72) Inventors: Wei-Pang Lee, Taipei City (TW); Shih-Chieh Su, Taipei City (TW); Shih-Kai Chou, Taipei City (TW)

(73) Assignee: PEGATRON CORPORATION, TAIPEI CITY (TW)

(21) Appl. No.: 18/411,481

(22) Filed: Jan. 12, 2024

(30) Foreign Application Priority Data
Mar. 1, 2023 (TW) 112107281

(51) Int. Cl. F28F 3/04; F28F 9/22

(52) U.S. Cl. CPC F28F 3/048; F28F 9/22; F28F 2009/228

(57) ABSTRACT

A water-cooling structure includes a heat sink, a cover plate, a heat exchange module, a retaining wall, and ribs. The heat sink has an inlet hole, an outlet hole, and an inner space which communicates with the inlet hole and the outlet hole. The cover plate is disposed on the heat sink to seal the inner space. The heat exchange module and the retaining wall are disposed on the cover plate and located in the inner space. The inlet hole and the outlet hole are disposed on different sides of the retaining wall. The ribs are disposed on the cover plate and form flow channels in the inner space. A coolant enters the inner space from the inlet hole, enters the flow channels along the retaining wall to contact the heat exchange module, and flows out of the outlet hole after passing through the heat exchange module.

### CROSS-REFERENCE TO RELATED APPLICATION

This application claims the priority benefit of Taiwan patent application no. 112107281, filed on Mar. 1, 2023. The entirety of the above-mentioned patent application is hereby incorporated by reference herein and made a part of this specification.

### BACKGROUND

### Technical Field

The disclosure relates to a device configured to dissipate heat; more particularly, the disclosure relates to a water-cooling structure.

### Description of Related Art

A water-cooling structure is an indispensable component in large machinery or automobiles. The conventional water-cooling structure typically incorporates a plurality of heat sink fins and establishes a unidirectional coolant flow path, thus facilitating a coolant to enter through an inlet and pass through the heat sink fins. During the flow process, the coolant and the heat sink fins exchange heat to reduce the temperature of the heat sink fins, and then the coolant passes through the heat sink fins and is discharged via an outlet.

However, most components of the conventional water-cooling structure are secured by screws, which results in intricate assembly procedures, substantial spatial requirements, and elevated production costs. In the conventional water-cooling structure, the internal heat sink fins and various ribs necessitate separate manufacturing and subsequent soldering steps. Inadequate soldering may easily introduce thermal resistance and detrimentally affect the heat dissipation efficiency.

Moreover, the configuration of the flow channels in the water-cooling structure is constrained by a stamping process, thereby hindering the ability to enhance the flow speed through diversion.

### SUMMARY

The disclosure provides a water-cooling structure with a plurality of integrally formed ribs to generate a plurality of flow channels. When a coolant flows in the water-cooling structure, the coolant is diverted by a plurality of flow channels, thereby increasing a flow speed of the coolant and the heat dissipation efficiency.

In an embodiment of the disclosure, a water-cooling structure includes a heat sink, a cover plate, a heat exchange module, a retaining wall, and a plurality of ribs. The heat sink has an inlet hole, an outlet hole, and an inner space. The inner space communicates with the inlet hole and the outlet hole. The cover plate is disposed on the heat sink to seal the inner space. The heat exchange module is disposed on the cover plate and located in the inner space. The retaining wall is disposed on the cover plate and located in the inner space, and the inlet hole and the outlet hole are disposed on different sides of the retaining wall. The ribs are disposed on the cover plate and located in the inner space to form a plurality of flow channels. A coolant enters the inner space from the inlet hole, enters the flow channels along the retaining wall to contact the heat exchange module, and flows out of the outlet hole after passing through the heat exchange module.

According to an embodiment of the disclosure, the heat exchange module, the retaining wall, and the ribs are all formed on the cover plate in a die-casting manner.

According to an embodiment of the disclosure, the heat exchange module has a first fin assembly and a second fin assembly respectively located on two sides of the retaining wall, the first fin assembly is positioned near the inlet hole, and the second fin assembly is positioned near the outlet hole.

According to an embodiment of the disclosure, the ribs are located on one of the two sides of the retaining wall near the outlet hole and connected to the second fin assembly.

According to an embodiment of the disclosure, the ribs are located on one of the two sides of the retaining wall near the inlet hole and connected to the first fin assembly.

According to an embodiment of the disclosure, the ribs are located on both the two sides of the retaining wall and respectively connected to the first fin assembly and the second fin assembly.

According to an embodiment of the disclosure, the number of the ribs includes two, so as to divide the flow channels into three flow channels.

According to an embodiment of the disclosure, the heat sink has a locking groove, and the cover plate is disposed in the locking groove.

According to an embodiment of the disclosure, the water-cooling structure further includes a first passage and a second passage that are disposed on a top surface of the heat sink and respectively communicate with the inlet hole and the outlet hole.

According to an embodiment of the disclosure, the heat sink and the cover plate are interconnected by soldering, riveting, or adhesion.

In light of the foregoing, the water-cooling structure provided in one or more embodiments of the disclosure is equipped with the integrally formed ribs on the cover plate to divide the inner space into the flow channels. When the coolant enters the inner space from the inlet hole, the coolant flows into the flow channels along the retaining wall. Therefore, the coolant is diverted by the flow channels. One part of the coolant is guided to a key heat dissipation region and stays for a longer time, thus enabling sufficient heat exchange between the coolant and the heat exchange module. The other part of the coolant quickly passes through the heat exchange module to avoid stagnation. The water-cooling structure provided in one or more embodiments of the disclosure adopts the design of a plurality of flow channels to optimize the flow speed and the heat dissipation efficiency.

To make the above more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a schematic three-dimensional diagram of a water-cooling structure according to an embodiment of the disclosure.

FIG. 2 is a schematic three-dimensional diagram of the water-cooling structure in FIG. 1 in another direction.

FIG. 3 is a schematic exploded diagram of components of the water-cooling structure in FIG. 1.

FIG. 4 is a schematic exploded diagram of components of the water-cooling structure in FIG. 2.

FIG. 5 is a schematic perspective plane diagram of the water-cooling structure in FIG. 1.

FIG. 6 is a schematic perspective plane diagram of a water-cooling structure according to another embodiment of the disclosure.

FIG. 7 is a schematic perspective plane diagram of a water-cooling structure according to another embodiment of the disclosure.

### DESCRIPTION OF THE EMBODIMENTS

The embodiments of the disclosure are provided below for the purpose of clarity, and details for implementation are incorporated below. Moreover, wherever possible, elements/components/steps with the same reference numbers in the drawings and the embodiments denote the same or similar parts.

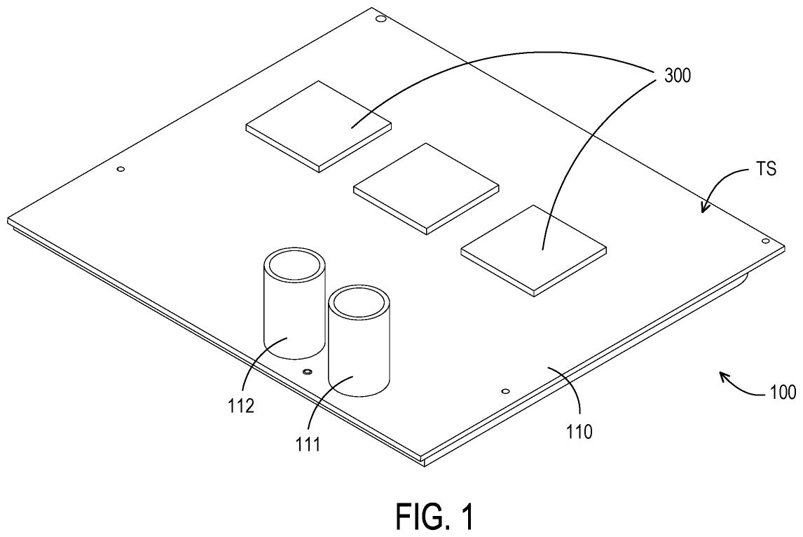

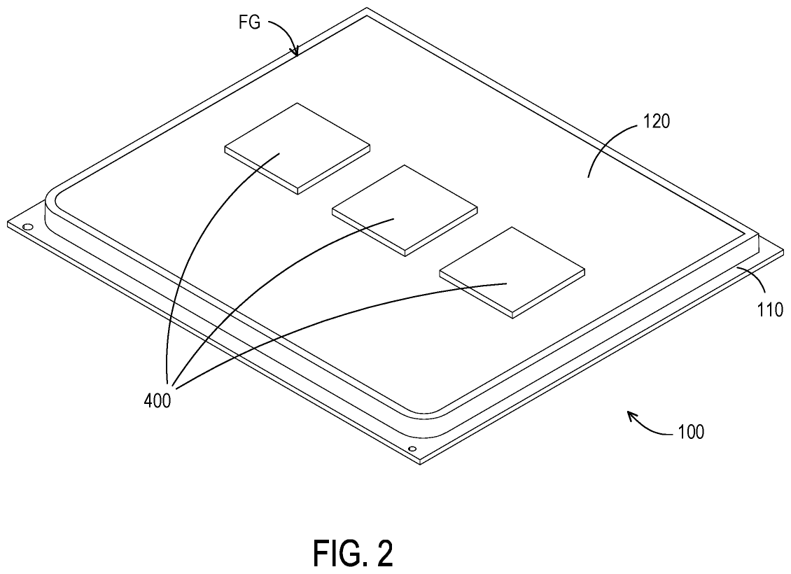

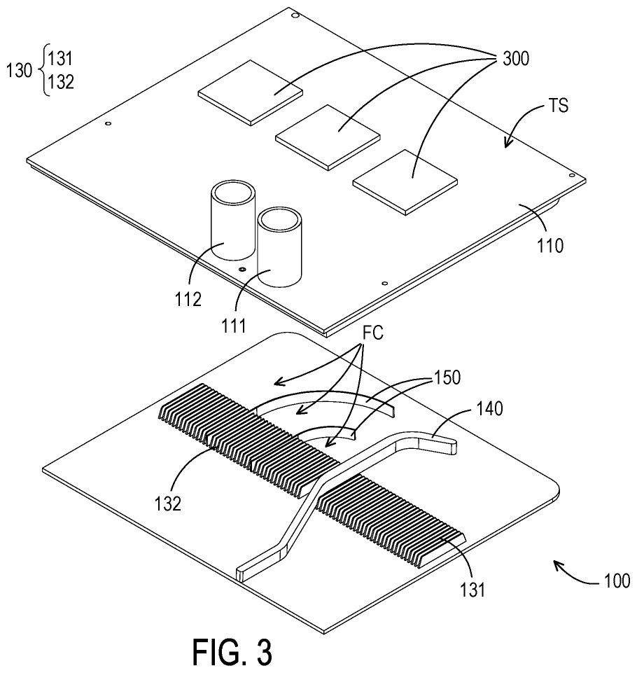

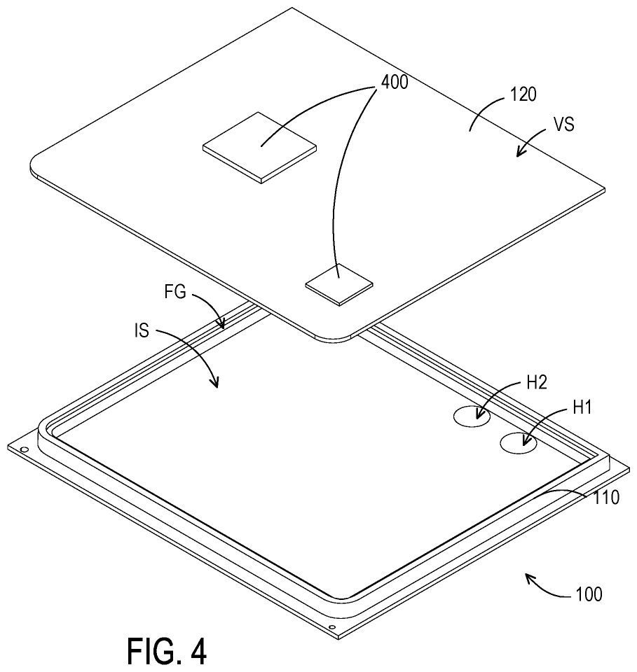

FIG. 1 is a schematic three-dimensional diagram of a water-cooling structure according to an embodiment of the disclosure. FIG. 2 is a schematic three-dimensional diagram of the water-cooling structure in FIG. 1 in another direction. FIG. 3 is a schematic exploded diagram of components of the water-cooling structure in FIG. 1. FIG. 4 is a schematic exploded diagram of components of the water-cooling structure in FIG. 2.

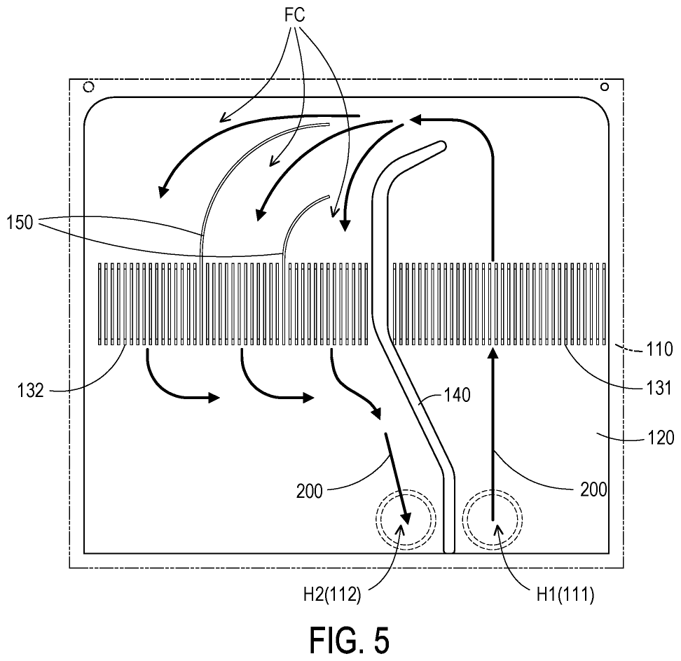

FIG. 5 is a schematic perspective plane diagram of the water-cooling structure in FIG. 1.

With reference to FIG. 1 and FIG. 2, a water-cooling structure 100 provided in an embodiment of the disclosure is applicable to large machinery or automobiles and is configured to contact a plurality of heat sources 300 and 400. Through heat conduction, the heat from the heat sources 300 and 400 is transferred to the water-cooling structure 100, and then heat exchange is performed between a circulating coolant and the water-cooling structure 100, so as to dissipate the heat and achieve heat dissipation. In addition, the water-cooling structure 100 is a sealed structure with an inner space, and the shape of the water-cooling structure 100 may be adjusted according to where the water-cooling structure 100 is placed.

With reference to FIG. 1 to FIG. 4, the water-cooling structure 100 provided in an embodiment of the disclosure includes a heat sink 110, a cover plate 120, a heat exchange module 130, a retaining wall 140, and a plurality of ribs 150.

The heat sink 110 has an inlet hole H1, an outlet hole H2, and an inner space IS. The inlet hole H1 and the outlet hole H2 penetrate a top surface TS of the heat sink 110, and the inner space IS is formed at the bottom of the heat sink 110 and communicates with the inlet hole H1 and the outlet hole H2. The cover plate 120 is disposed on the heat sink 110 to seal the inner space IS. In detail, the heat sink 110 and the cover plate 120 are interconnected by soldering, riveting, or adhesion, and the heat sink 110 has a locking groove FG. The cover plate 120 is disposed in the locking groove FG to seal the inner space IS.

The heat sink 110 and the cover plate 120 are made of metal or ceramic materials with high thermal conductivity. The heat exchange module 130 is disposed on the cover plate 120 and located in the inner space IS. The retaining wall 140 is disposed on the cover plate 120 and located in the inner space IS. With reference to FIG. 5, the inlet hole H1 and the outlet hole H2 are disposed on different sides of the retaining wall 140; that is, the retaining wall 140 is adapted to separate the inlet hole H1 and the outlet hole H2. The ribs 150 are disposed on the cover plate 120 and form a plurality of flow channels FC in the inner space IS.

In addition, the heat sink 110 further includes a first passage 111 and a second passage 112, which are vertically disposed on the top surface TS of the heat sink 110 and respectively communicate with the inlet hole H1 and the outlet hole H2. A coolant 200 is suitable for entering the inner space IS through the first passage 111 and the inlet hole H1, contacts the heat exchange module 130 through the flow channels FC, and flows out of the outlet hole H2 and the second passage 112 after passing through the heat exchange module 130. The next cooling cycle then continues.

With reference to FIG. 1 and FIG. 2, the top surface TS of the heat sink 110 is configured to contact the heat source 300, and a bottom surface of the cover plate 120, which is far from the inner space IS, is configured to contact the heat source 400. The water-cooling structure 100 further includes a plurality of support columns respectively disposed on the top surface TS of the heat sink 110 and the bottom surface of the cover plate 120. The support columns are located around the heat source 300 and the heat source 400 and configured to maintain a gap between the heat sink 110 or the cover plate 120 and machinery or automobile parts (not shown).

With reference to FIG. 3 and FIG. 4, the heat exchange module 130, the retaining wall 140, and the ribs 150 are all formed on the cover plate 120 in a die-casting manner. As such, it is no longer necessary to solder the heat exchange module 130, thus preventing the introduction of thermal resistance due to inappropriate soldering processes and thus detrimentally affecting the heat dissipation efficiency. In addition, the number and the guiding direction of the flow channels may be determined according to actual needs, and the retaining wall 140 and the ribs 150 may be integrally formed on the cover plate 120 through die-casting, so as to resolve the issue that the flow channels cannot be easily formed in the conventional water-cooling structure in a stamping process.

With reference to FIG. 3 and FIG. 5, particularly, the heat exchange module 130 has a first fin assembly 131 and a second fin assembly 132 respectively located on both sides of the retaining wall 140. The first fin assembly 131 is positioned near the inlet hole H1, and the second fin assembly 132 is positioned near the outlet hole H2. The ribs 150 are located on one of the two sides of the retaining wall 140 near the outlet hole H2 and connected to the second fin assembly 132; that is, the ribs 150 form a plurality of flow channels FC on one of the two sides of the outlet hole H2. In this embodiment, the number of the ribs 150 includes two, so as to divide the flow channels FC into three flow channels FC.

With reference to FIG. 1 and FIG. 5, a cooling process of the water-cooling structure 100 is described in detail below. The coolant 200 is introduced from the first passage 111 and enters the inner space IS of the heat sink 110 through the inlet hole H1. The coolant 200 flows and contacts the first fin assembly 131 and flows along the retaining wall 140 to the ribs 150, so that the coolant 200 is diverted and enters the flow channels FC. The diverted coolant 200 flows downward and contacts the second fin assembly 132, and the diverted coolant 200 converges after passing through and contacting the second fin assembly 132 and is discharged from the outlet hole H2 through the second passage 112.

When the coolant 200 passes through the flow channels FC, turbulent flows are generated due to the interference of the ribs 150, which slows down the flow speed of the coolant 200 in the flow channels FC. As such, the coolant 200 stays longer in the second fin assembly 132, so that the coolant 200 is able to sufficiently exchange heat with the second fin assembly 132.

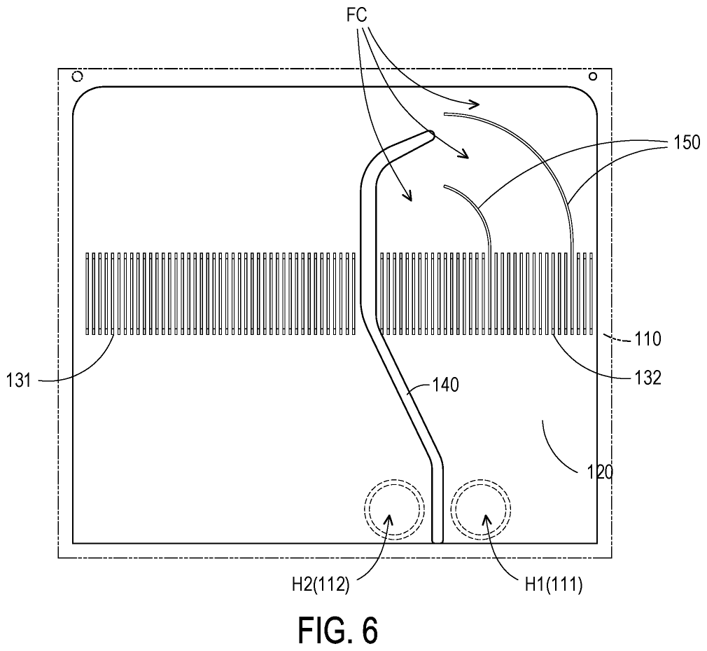

FIG. 6 is a schematic perspective plane diagram of a water-cooling structure according to another embodiment of the disclosure.

With reference to FIG. 6, in this embodiment, the ribs 150 are located on one side of the retaining wall 140 near the inlet hole H1 and connected to the first fin assembly 131. That is, the ribs 150 form the flow channels FC on the side near the inlet hole H1. When the coolant 200 enters the inner space IS from the inlet hole H1, the coolant 200 first passes through the first fin assembly 131 and then flows into the respective flow channels FC to achieve diversion. Afterwards, the coolant 200 converges and enters the other side of the retaining wall 140 to pass through the second fin assembly 132, and finally, the converged coolant 200 is discharged from the outlet hole H2, which explains that the heat source is located on the side of the retaining wall 140 near the inlet hole H1, and therefore the ribs 150 serve to reduce the flow speed of the coolant 200.

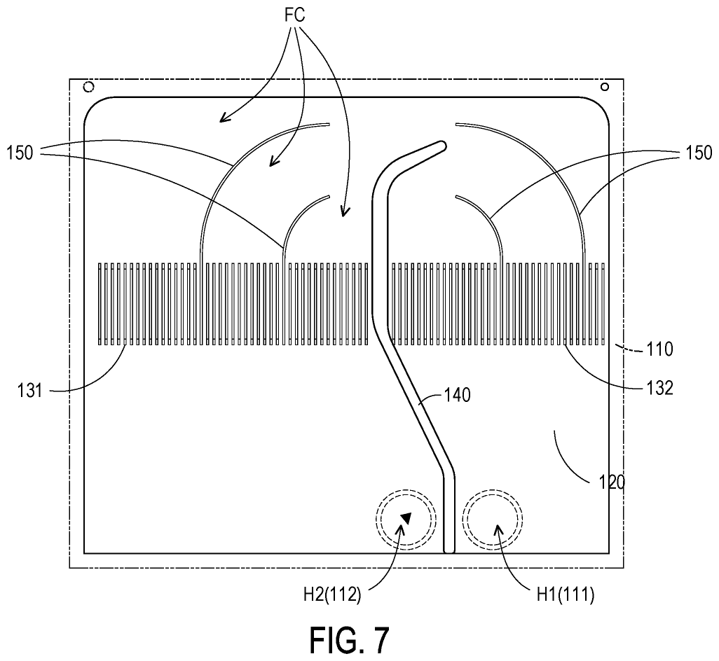

FIG. 7 is a schematic perspective plane diagram of a water-cooling structure according to another embodiment of the disclosure.

With reference to FIG. 7, in this embodiment, the ribs 150 are located on both sides of the retaining wall 140 and respectively connected to the first fin assembly 131 and the second fin assembly 132. That is, the ribs 150 form the flow channels FC on both sides of the retaining wall 140. When the coolant 200 enters the inner space IS from the inlet hole H1, the coolant 200 first passes through the first fin assembly 131 and then flows into the flow channels FC on the right side of the retaining wall 140 to achieve the diversion. Afterwards, the coolant 200 converges and enters the flow channels FC on the left side of the retaining wall 140, and the coolant 200 passes through the second fin assembly 132 through a secondary diversion. Finally, the coolant 200 passing through the second fin assembly 132 is discharged from the outlet hole H2, which explains that heat sources exist on both sides of the retaining wall 140, and through a two-stage diversion, the flow speed of the coolant 200 through the first fin assembly 131 and the second fin assembly 132.

To sum up, the water-cooling structure provided in one or more embodiments of the disclosure is equipped with the integrally formed ribs on the cover plate to divide the inner space into the flow channels. When the coolant enters the inner space from the inlet hole, the coolant flows into the flow channels along the retaining wall. Therefore, the coolant is diverted by the flow channels. One part of the coolant is guided to a key heat dissipation region and stays for a longer time, thus enabling sufficient heat exchange between the part of the coolant and the heat exchange module. The other part of the coolant quickly passes through the heat exchange module to avoid stagnation. The water-cooling structure provided in one or more embodiments of the disclosure adopts the design of a plurality of flow channels to optimize the flow speed and the heat dissipation efficiency.

It will be apparent to those skilled in the art that various modifications and variations may be made to the disclosed embodiments without departing from the scope or spirit of the disclosure. In view of the foregoing, it is intended that the disclosure covers modifications and variations provided they fall within the scope of the following claims and their equivalents.

What is claimed is:

1. A water-cooling structure, comprising:
a heat sink, having an inlet hole, an outlet hole, and an inner space, wherein the inner space communicates with the inlet hole and the outlet hole;
a cover plate, disposed on the heat sink to seal the inner space;
a heat exchange module, disposed on the cover plate and located in the inner space;
a retaining wall, disposed on the cover plate and located in the inner space, wherein the inlet hole and the outlet hole are disposed on different sides of the retaining wall; and
a plurality of ribs, disposed on the cover plate and located in the inner space to form a plurality of flow channels,
wherein a coolant enters the inner space from the inlet hole, enters the flow channels along the retaining wall to contact the heat exchange module, and flows out of the outlet hole after passing through the heat exchange module.

2. The water-cooling structure as claimed in claim 1, wherein the heat exchange module, the retaining wall, and the ribs are all formed on the cover plate in a die-casting manner.

3. The water-cooling structure as claimed in claim 1, wherein the heat exchange module has a first fin assembly and a second fin assembly respectively located on two sides of the retaining wall, the first fin assembly is positioned near the inlet hole, and the second fin assembly is positioned near the outlet hole.

4. The water-cooling structure as claimed in claim 3, wherein the ribs are located on one of the two sides of the retaining wall near the outlet hole and connected to the second fin assembly.

5. The water-cooling structure as claimed in claim 3, wherein the ribs are located on one of the two sides of the retaining wall near the inlet hole and connected to the first fin assembly.

6. The water-cooling structure as claimed in claim 3, wherein the ribs are located on both the two sides of the retaining wall and respectively connected to the first fin assembly and the second fin assembly.

7. The water-cooling structure as claimed in claim 4, wherein the number of ribs includes two, so as to divide the flow channels into three flow channels.

8. The water-cooling structure as claimed in claim 5, wherein the number of ribs includes two, so as to divide the flow channels into three flow channels.

9. The water-cooling structure as claimed in claim 1, wherein the heat sink has a locking groove, and the cover plate is disposed in the locking groove.

10. The water-cooling structure as claimed in claim 1, further comprising a first passage and a second passage disposed on a top surface of the heat sink and respectively communicating with the inlet hole and the outlet hole.

11. The water-cooling structure as claimed in claim 1, wherein the heat sink and the cover plate are interconnected by soldering, riveting, or adhesion.
